(19) United States
(12) Patent Application Publication
(10) Pub. No.: US 2020/0335432 A1
(43) Pub. Date: Oct. 22, 2020

(54) CHIP MOUNTING TECHNIQUES TO REDUCE CIRCUIT BOARD DEFLECTION

(71) Applicant: Intel Corporation, Santa Clara, CA (US)

(72) Inventors: Gregorio R. Murtagian, Phoenix, AZ (US); Jeffory L. Smalley, East Olympia, WA (US); Thomas T. Holden, Grass Valley, CA (US); Silver A. Estrada Rodriguez, Zapopan (MX); Luis E. Rosales Galvan, Portland, OR (US)

(73) Assignee: Intel Corporation, Santa Clara, CA (US)

(21) Appl. No.: 16/388,136

(22) Filed: Apr. 18, 2019

(51) Int. Cl. H01L 23/498; H01L 21/67; H05K 1/18

(52) U.S. Cl. CPC H01L 23/49833; H05K 1/181; H01L 21/67144

(57) ABSTRACT

A circuit board assembly includes at least one circuit board having a plurality of conductive layers, the at least one circuit board having a first face and an opposite second face. A first chip socket on the first face is positioned opposite of a second chip socket on the second face. In one example, each chip socket can receive a processor. The first and second chip sockets may be arranged in a mirrored fashion with respect to one another, or an overlapping but non-mirrored fashion. In any such arrangements, as fasteners are tightened to fully seat first and second chips respectively installed in the first and second chip sockets, forces applied to the first chip effectively neutralize or otherwise reduce opposing forces applied to the second chip, thereby reducing circuit board deflection.

### BACKGROUND

A land grid array (LGA) is a type of surface-mount packaging for components on a printed circuit board (PCB). For example, an LGA socket can be electrically connected to a printed circuit board by way of a plurality of pins and may be used as a physical interface for a microprocessor or other integrated circuit that has an array of contact pads or lands as its input/output interface. One example of an LGA socket has pins that make contact not only with the underlying PCB but also with corresponding lands on the bottom surface of the microprocessor designed for engagement with that socket. The microprocessor can be installed in the socket using a load plate and frame that are connected together with fasteners. Installing the microprocessor in the socket may be done by hand. For example, the microprocessor is positioned in the socket, a heat sink assembly is installed on top of the microprocessor, and the heat sink assembly is then secured to the circuit board using fasteners, thereby pressing the microprocessor down into the socket and making electrical contact between the pins of the socket and the lands of the microprocessor.

As the demand for computing power increases, so does the requirement for efficient use of space in computing equipment. For example, some server computers are manufactured to be rack mounted and to conform to standard form factors. For example, a standard rack space has a width of 19 inches and a height of 1.75″ (44.5 mm). The vertical size of this rack space is known as one rack unit or 1U. Rack-mounted computing equipment can be assembled into a chassis that is sized to occupy 1U, 2U, 3U, 4U or other vertical size. For example, server computers are often sized in 1U or 2U configurations. It is desirable to provide a smaller product size when possible and to maximize the density of computing power in a server rack, for example. As processor power increases, the number of contacts (e.g., pins or lands) in a processor socket also increases. For example, some LGA sockets on a computer server motherboard have 4000 contacts, but this number of contacts may more than double in the coming years and is expected to further increase. With an increase in the number of contacts in the socket, the socket size also increases, and so does the mechanical load needed to properly install the processor into the socket so that all of the lands of the processor make reliable electrical contact with corresponding contacts in the socket. For example, a load is applied at locations around the edges of the chip package (e.g., central processing unit or CPU) placed into the socket. As the load is applied to a socket on only one side of a circuit board, the circuit board tends to bend or deflect away from the center of the chip package. The result is that some lands on the chip package may not make reliable electrical contact with the socket, resulting in electrical opens and non-functioning systems. There are some techniques to address this circuit board deflection, but a number of non-trivial issues remain.

### BRIEF DESCRIPTION OF THE DRAWINGS

FIG. 1 is a plan view of one side of a circuit board assembly, in accordance with an embodiment of the present disclosure.

FIG. 2 is an exploded perspective view showing an example of an assembly that includes a circuit board, a socket, and a chip, in accordance with an embodiment of the present disclosure.

FIG. 3A is a plan view of a land grid array (LGA) socket, in accordance with an embodiment of the present disclosure.

FIG. 3B is a plan view of a chip package configured to be installed in the socket of FIG. 3A, in accordance with an embodiment of the present disclosure.

FIG. 4 is a cross-sectional view of a circuit board assembly as taken along line A-A of FIG. 1 and showing sockets in mirrored locations on both sides of the circuit board, in accordance with an embodiment of the present disclosure.

FIG. 5 is a cross-sectional view of a circuit board assembly as taken along line A-A of FIG. 1 and showing sockets in mirrored locations on circuit boards assembled back to back, in accordance with another embodiment of the present disclosure.

FIG. 6 is a cross-sectional view of a circuit board assembly as taken along line A-A of FIG. 1 and showing sockets in mirrored locations on circuit boards assembled back to back with a spacer between the circuit boards, in accordance with another embodiment of the present disclosure.

FIG. 7 is a cross-sectional view of a circuit board assembly as taken along line A-A of FIG. 1 and showing sockets in mirrored locations on circuit boards assembled back to back with a spacer between portions of the circuit boards, in accordance with another embodiment of the present disclosure.

FIG. 8 is a cross-sectional view of the circuit board assembly of FIG. 4 shown assembled with chip packages and memory cards, in accordance with an embodiment of the present disclosure.

FIG. 9 is a cross-sectional view of the circuit board assembly of FIG. 5 shown assembled with chip packages, in accordance with an embodiment of the present disclosure.

FIG. 10 is a cross-sectional view of the circuit board assembly of FIG. 6 shown assembled with chip packages, in accordance with an embodiment of the present disclosure.

FIG. 11 is a cross-sectional view of the circuit board assembly of FIG. 7 shown assembled with chip packages, in accordance with an embodiment of the present disclosure.

FIGS. 12A-12E illustrate plan views of various non-mirrored but overlapping orientations between chip sockets on opposite sides of a circuit board or circuit board assembly, in accordance with some embodiments of the present disclosure.

FIG. 13 illustrates a computing system utilizing one or more circuit board assemblies, in accordance with an embodiment of the present disclosure.

The figures depict various embodiments of the present disclosure for purposes of illustration only. Numerous variations, configurations, and other embodiments will be apparent from the following detailed discussion.

### DETAILED DESCRIPTION

Disclosed is a circuit board assembly with chip sockets attached to opposite faces of the assembly. In some embodiments, the chip sockets on opposite faces have the same size and the location of the chip sockets is also the same, such that the two sockets are mirrored with respect to each other. In other embodiments, a first chip socket on a first face at least partially overlaps a second chip socket on an opposite second face in a non-mirrored orientation. In some such embodiments, the first and second chip sockets can have the same or different size. In other such embodiments, the chip sockets on opposite faces can be rotated with respect to one another. In yet other embodiments, chip sockets on opposite faces are positioned to at least partially overlap each other, including being aligned and centered, having an offset arrangement, being rotated 90° to each other, and other positional variations. In any such arrangements, as fasteners are tightened to fully seat first and second chips respectively installed in the first and second chip sockets, forces applied to the first chip effectively counter opposing forces applied to the second chip, thereby reducing circuit board deflection.

In one specific example embodiment, the circuit board assembly utilizes one or more sockets on each face of a circuit board. Each socket is aligned in a mirror-like fashion with a socket on the opposite face of the circuit board to provide a mirrored socket-pair, such that fasteners used to secure the sockets to the circuit board can be installed through holes common to both sockets on opposite faces of the circuit board. In another example, the circuit board assembly includes two circuit boards mounted back-to-back. In some such cases, the circuit board assembly optionally includes a spacer between the back-to-back circuit boards. In some such cases, the spacer continuously spans the entire distance between the circuit boards, while in other such cases the spacer is non-continuous leaving one or more openings or voids between the circuit boards. Similar to an assembly having a single circuit board, the socket-pairs are mounted to opposite faces of the circuit board assembly and have a mirrored arrangement. In still other embodiments, the sockets on opposite faces of the circuit board assembly are offset and/or rotated with respect to each other, so as to at least partially overlap but in a non-mirrored arrangement. Numerous variations and embodiments will be apparent in light of the present disclosure.

### General Overview

As previously noted, there are a number of techniques to address the mechanical deflection of a PCB when installing a chip into an LGA socket, but a number of non-trivial issues remain. In more detail, one possible solution to reduce deflection of the circuit board is to increase the stiffness of the circuit board assembly. One such solution uses a metal back plate on the back side of the PCB, a bolster plate on the front side of the PCB, or both. However, current form factors limit the thickness of the back plate to 2.3 mm. Adding a bolster plate to the front side of the board adds cost, complexity, and reduces the space available for component placement. Another solution uses a thicker circuit board. However, since computing hardware is already sized to completely fill the available space in a chassis, and since the vertical size of a rack-mounted chassis is constrained by the dimensions of the standard rack unit, very little, if any, space is available to increase the thickness of the assembly. Doing so would require reducing the physical dimensions of computing components, and therefore reducing computing power. So, such solutions are not suitable for some applications, such as those necessitating a high level of computing power. Alternately, the electronic device including a thicker circuit board may need to be installed in a 2U chassis instead of a 1U chassis to accommodate the thicker and additional materials in the socket assembly, thereby effectively halving the computing density for that rack installation.

Another approach to better enable CPUs in an LGA socket is to increase the number of fasteners around the outside of the socket in an attempt to better distribute the load applied to the chip package. For example, instead of using fasteners at the corners only, some LGA sockets have seven or more fasteners in locations around the frame of the socket. Since each fastener requires a hole through the circuit board, the use of additional fasteners reduces the available space for electrical connections and conductive traces. So, such an approach is not practical for some applications, such as those necessitating a dense field of conductors. Additionally, these additional fasteners may not adequately address PCB deflection as a load is applied.

Yet another approach to reducing circuit board deflection is to add a ring of insulating material between the central region of the chip package and the circuit board. As the fasteners are tightened, the ring increases stiffness of the assembly around the central region and therefore can reduce circuit board deflection. Such a solution, however, is relatively complex and adds significant expense to the assembly. Yet another possible solution is to reduce the per-contact load. However, such solutions have been found to increase the contact resistance and therefore reduce the power delivery efficiency of the computing system.

In addition to limitations noted above, these approaches may not continue to be effective at all as the socket size and mechanical load continue to increase. Accordingly, a need exists for improved techniques for enabling low-deflection installation of a chip package (e.g., CPU chip) in a chip socket while also working within the physical dimensions of established form factors for computing equipment and other electronic systems that utilize LGA-type sockets with relatively large pin counts. The present disclosure addresses this need, among others.

In accordance with one embodiment of the present disclosure, a circuit board assembly includes processors on opposite faces of the circuit board. For example, in a computing system with eight processors, four processors are mounted to the first face and four processors are mounted to the opposite second face in positions mirroring the processors on the first face, according to one example embodiment. The present disclosure is not limited to a particular number of sockets and could apply to any number of sockets. A load is applied to opposite faces of the circuit board to enable the processors and/or to provide a good thermal interface for heat management. Since the load exerted on each processor is opposed by a load on a processor on the opposite face, and since the opposing processors are aligned or at least overlap, this approach simulates having an infinitely rigid backing plate with little or no circuit board deflection. Additionally, in some such embodiments, the requirement for a reduced mechanical load is largely removed, as deflection is neutralized or otherwise reduced. In addition, some such embodiments can eliminate the need for a backing plate or bolster plate for integrated circuit chips (e.g., CPUs). Additionally, solutions according to some embodiments of the present disclosure can maintain the current computing density by doubling the number of processors per circuit board. Other benefits and applications will be appreciated in light of this disclosure.

While the present disclosure is discussed with reference to LGA sockets, the present disclosure can apply to any socket that uses an enabling load or a load applied to enhance the thermal interface. Examples of applicable sockets include dual-compression sockets, hybrid sockets, ball grid array (BGA) sockets, and pin grid array (PGA) sockets to name a few examples. Additionally, some example embodiments are discussed for a motherboard, such as may be used in a rack-mounted server computer. The present disclosure is not limited to such applications and can be applied to a variety of circuit boards and electronic systems, particularly those that include a high pin count integrated circuit susceptible to relatively large force when being installed in a corresponding socket on a given circuit board. Numerous variations and embodiments will be apparent in light of the present disclosure.

### EXAMPLE EMBODIMENTS

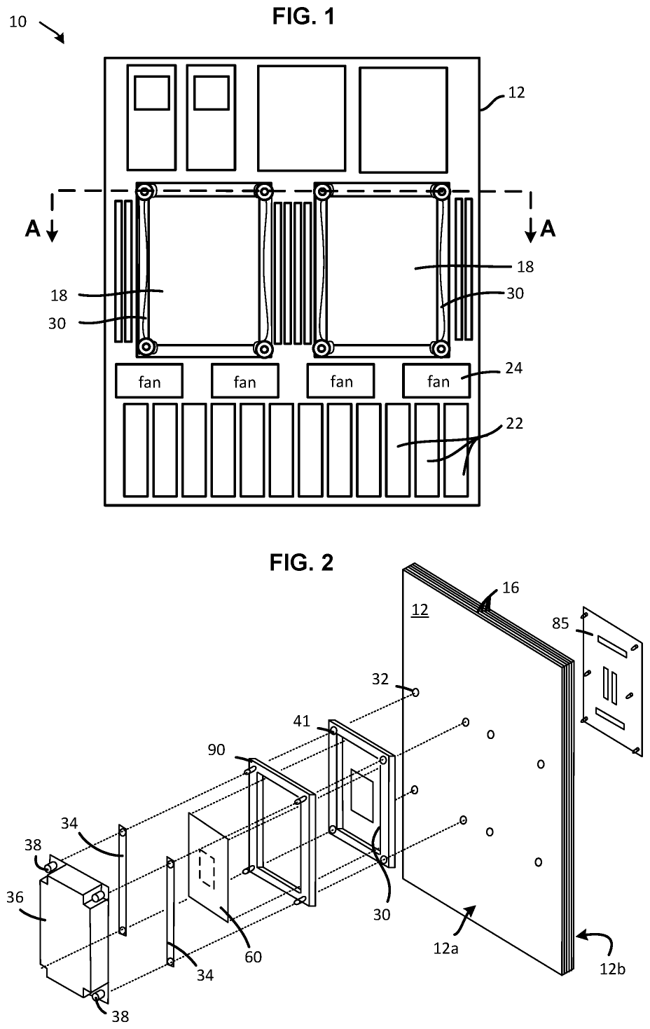

FIG. 1 illustrates a plan view of a circuit board assembly 10 in accordance with an embodiment of the present disclosure. In one example, the circuit board assembly 10 includes a laminated circuit board 12 that includes a substrate 14 and one or more conductive layers 16 (not shown), such as copper, in a laminated assembly. The substrate 14 may comprise fiberglass, phenolic, or other suitable electrically insulative material, as will be appreciated. The circuit board can include one, two, four, eight, twelve, or other number of conductive layers 16. Circuit components are mounted on the circuit board 12 and make electrical contact with conductive traces or the like formed in one or more conductive layers 16, as will be appreciated. The circuit board assembly 10 may be configured as a motherboard, a daughter board, a network card, or other circuit board. In the example shown in FIG. 1, the circuit board assembly 10 is configured as a motherboard for a server computer and includes one or more processors 18, one or more random access memory chip slot 20 (e.g., for dual in-line memory modules or “DIMMs”), hard disk drives 22, fans 24, connectors for integrated peripherals, and other components. Numerous embodiments and variations will be apparent in light of the present disclosure.

FIG. 2 illustrates an exploded perspective view showing an example assembly of a chip package 60, socket 30, and circuit board 12. Optional backing plate 85 and optional bolster plate 90 can be included as stiffening components, in accordance with some embodiments. In the example shown, the circuit board 12 has a laminated structure that includes a plurality of conductive layers 16 (e.g., four, eight, twelve, or more conductive layers 16). In some embodiments, the conductive layers 16 include a first set of conductive layers configured with electrical connections to the first side 12a of the circuit board and a second set of conductive layers configured with electrical connections to the second side 12b of the circuit board 12. In one embodiment, each chip package 60 is installed in a land grid array (LGA) socket 30 so that it is enabled, meaning contacts on the chip package 60 make electrical contact with respective contacts in the socket 30. The circuit board 12 defines a plurality of through openings 32 sized for fasteners 38. The socket 30 is placed against the circuit board 12 with fastener openings 41 aligned with the openings 32 in the circuit board 12. The chip package 60 is configured to be installed in a frame defined by the socket 30. In one example, the chip package 60 includes a processor 18, a package substrate, a housing, shielding, and/or any other components needed for a given application, as will be appreciated. Springs 34, such as leaf springs, coil-less springs, coil springs, or torsion springs, are positioned to distribute forces of the fasteners 38. For example, springs 34 are placed between a heat sink 36 and the chip package 60. When the heat sink 36 is secured to the circuit board 12 using fasteners 38 that extend through the openings 32, for example, the heat sink 36 and springs 34 apply a generally distributed load to the chip package 60 to press it into the socket 30 and enable the processor 18. Although the example of FIG. 2 shows chip package 60, socket 30, and other components ready to be mounted on a first face 12a of the circuit board 12, sockets 30 can be similarly mounted to the opposite second face 12b of the circuit board 12 such that sockets 30 on opposite faces of the circuit board 12 mirror each other or at least partially overlap each other, in accordance with some embodiments of the present disclosure. Examples of such embodiments are discussed in more detail below.

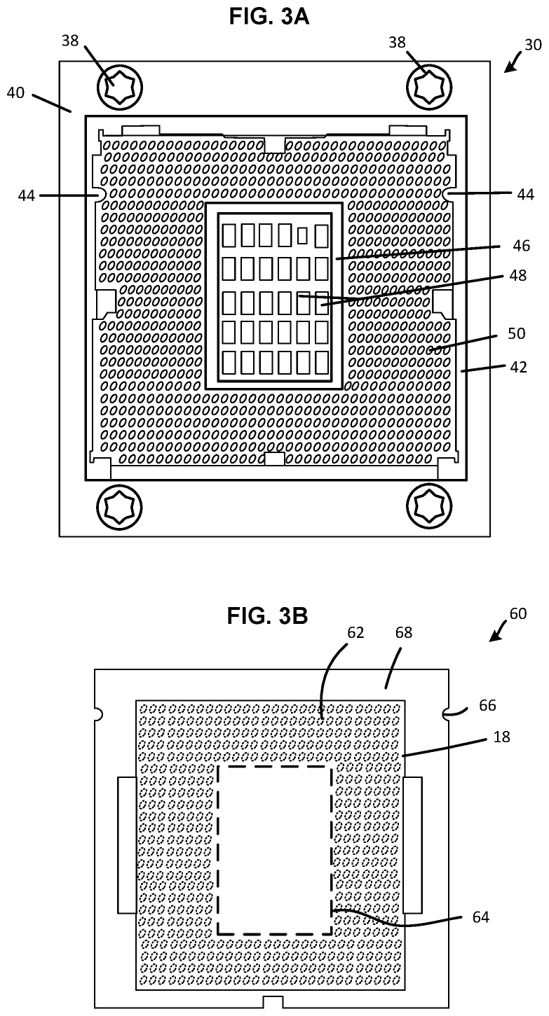

Referring now to FIG. 3A, a top plan view illustrates an example of a socket 30 in accordance with an embodiment of the present disclosure. The socket 30 has an exterior socket wall or frame 42 that generally defines a rectangular shape to receive a package, such as a processor chip. The socket 30 may include fastener tabs 40 that extend from the frame 42 and that are configured to accept fasteners 38 through fastener openings 41 to secure the socket 30 to the circuit board 12. In another embodiment, the fastener tabs 40 include a post, threaded receptacle, or other integral fastener component that is configured to mate with a corresponding second fastener component. In other embodiments, fastener openings 41 are defined in the frame 42 or other suitable location. The frame 42 optionally defines one or more key notches 44 that extend inward from the frame 42 and that can be used to correctly position a chip package 60 in the socket 30 with pins or other contacts 50 in contact with corresponding lands or other chip connectors 62 on the chip package 60, for example. In some embodiments, the socket 30 defines a central region 46 or center cavity with capacitors, resistors, and/or other circuit components 48 used with the processor 18. The central region 46 may be isolated from other portions of the socket 30 by a frame or wall 47 extending around the central region 46. A grid of contacts 50 (e.g., pins) are positioned within the frame 42 to make contact with respective contacts 62 (e.g., lands) on the bottom surface of the chip package 60. In one example, the contacts 50 have a pitch of about 1 mm or less. The socket 30 can have thousands of contacts 50, such as 4000, 5000, 6000, 7000, 8000, 9000, 10,000 or more.

Referring now to FIG. 3B, a top plan view illustrates an example of a chip package 60 that contains the processor 18, a cover, a chip substrate 19 and other components completing the chip package 60, as will be appreciated. The chip package 60 can be received in the socket 30 and has chip contacts 62 that correspond to contacts 50 in the socket 30. In some embodiments, the chip package 60 defines one or more alignment recesses 66 corresponding to the key notches 44 of the socket 30. In some embodiments, the chip package 60 may define a central region 64 that corresponds to the central region 46 of the socket 30. The central region 64 of the chip package 60 may include back side capacitors or other circuit components, as will be appreciated.

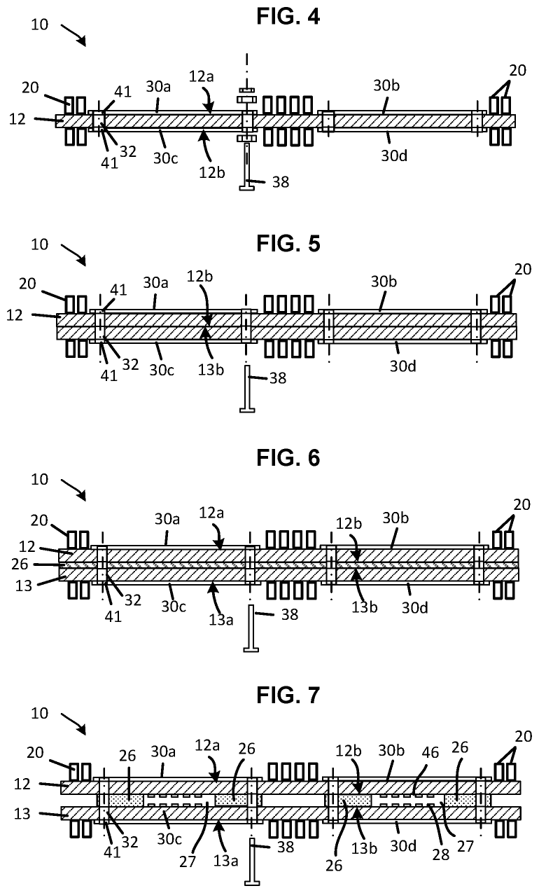

Referring now to FIGS. 4-7, cross-sectional views show example circuit board assemblies 10 where the section is taken along line A-A of FIG. 1, in accordance with some embodiments of the present disclosure. In the example of FIG. 4, the circuit board assembly 10 includes a circuit board 12 with sockets 30a, 30b mounted on a first side 12a of the circuit board 12 and sockets 30c, 30d mounted on a second side 12b of the circuit board 12. Each socket 30 defines fastener openings 41 that are aligned with openings 32 through the circuit board 12. Sockets 30a and 30b on the first side 12a are aligned with sockets 30c and 30d, respectively, on the second side 12b. Sockets 30 on opposite sides of the circuit board 12 are aligned with common fastener openings 41 so that a fastener 38 can extend through a given fastener opening 41 and engage opposite sockets 30 (and/or a heat sink 36, spring 34, or other components of the circuit board assembly 10), drawing opposite components towards the circuit board 12 when the fasteners 38 are tightened. In such an embodiment, the sockets 30 on the first side 12a mirror those on the second side 12b. Note that the arrangement of contacts 50 within each socket 30 need not be mirrored on each side of the circuit board 12 and need not have the same arrangement. Also, sockets 30 on opposite sides of the circuit board 12 need not be perfectly aligned, but as a general matter, are aligned within the tolerances permitted by fasteners 38, fastener openings 41, and openings 32 in the circuit board 12, in accordance with some embodiments. Sockets 30 may be secured to the circuit board 12 using adhesive, fasteners 38, solder connections to the circuit board 12, or a combination of these methods, as will be appreciated.

As illustrated in FIG. 4, additional components, such as memory chip slots 20, optionally can be arranged on the first side 12a and second side 12b of the circuit board 12 in a mirrored arrangement. Mirroring the location of the chip slots 20 and other additional components is not required since the problem of circuit board deflection generally does not apply to such components as it does to sockets 30. In some embodiments, chip slots 20 on the first side 12a have a ½-pitch offset with respect to chip slots 20 on the second side 12b to accommodate mounting features, for example. In one example, memory chip slots 20 on the first side 12a mirror the location of memory chip slots 20 on the second side 12b. Although two sockets 30 are shown on each side of the circuit board 12, the circuit board assembly 10 can have fewer sockets 30 (e.g., one socket 30 per side) or more sockets (e.g., three, four, six, or more sockets 30 per side) as deemed appropriate for the desired computing power and space available on the circuit board 12. Numerous embodiments and variations will be apparent in light of the present disclosure.

FIG. 5 illustrates a cross-sectional view of a circuit board assembly 10 that includes a first circuit board 12 and a second circuit board 13 mounted back-to-back, in accordance with an embodiment of the present disclosure. In this example, the second side 12b of the first circuit board 12 is assembled against the second side 13b of the second circuit board 13. Similar to the embodiment of FIG. 4, the location of socket 30a mirrors that of socket 30c and the location of socket 30b mirrors that of socket 30d. Consistent with the mirrored arrangement, fastener openings 41 on the sockets 30 and the openings 32 in the circuit boards 12, 13 are aligned to permit a fastener 38 to be installed therethrough.

In some embodiments, solder connections and other components may be recessed into the second sides 12b, 13b of one or both of the first circuit board 12 and second circuit board 13 to avoid contact between solder connections on the second sides 12b, 13b of the circuit boards 12, 13, respectively. For example, one or both circuit boards 12, 13 includes an additional substrate layer 14 that allows the solder connections and the like to be recessed below the surface. In one such embodiment, the additional substrate layer 14 can be machined to define locations where back-side components can be installed. Alternately, back-side components may be omitted; instead, front-side components may be used or electrical connections may be made to different conductive layers 16 in the respective circuit board 12, 13, as will be appreciated.

FIGS. 6 and 7 illustrate cross-sectional views of a circuit board assembly 10 that includes a first circuit board 12 and a second circuit board 13 mounted back-to-back with a spacer 26 disposed therebetween, in accordance with some embodiment of the present disclosure. In these examples, the spacer 26 is installed between and in contact with the second side 12b of the first circuit board 12 and the second side 13b of the second circuit board 13.

In some embodiments, the spacer 26 is made of an insulating material (e.g., fiberglass, phenolic, rubber, epoxy, etc.). Depending on its geometry and the locations where it contacts the circuit boards 12, 13, the spacer 26 may be made of or include metals or other conductive materials in some embodiments. In one embodiment, the spacer 26 can be a continuous sheet that generally contacts the entire second side 12b, 12b of the first and second circuit boards 12, 13. In one such embodiment, the spacer 26 can define through holes aligned with the openings 32 in the circuit boards 12, 13 and aligned with the fastener openings 41 in the sockets 30. Similar to the example illustrated in FIG. 4, the location of socket 30a mirrors that of socket 30c and the location of socket 30b mirrors that of socket 30d. Consistent with the mirrored arrangement, fastener openings 41 and openings 32 in the circuit boards 12, 13 are aligned to permit a fastener 38 to be installed therethrough.

In the embodiment of FIG. 7, the spacer 26 can be sized and shaped to face desired portions of the circuit boards 12, 13. For example, the spacer 26 is sized and shaped to contact less than the entire area of circuit boards 12, 13. In one embodiment, the spacer 26 is machined or otherwise shaped to contact the first circuit board 12 and the second circuit board 13 in specific locations. For example, the spacer 26 can be machined or otherwise formed to define recesses or through openings to avoid solder connections and the like. In some embodiments, the spacer 26 may include multiple distinct and separate portions that are located at desired locations between the circuit boards 12, 13. For example, one portion of the spacer 26 aligns at least in part with the region between the frame 42 and the central region 46 of the socket 30 (shown, e.g., in FIG. 3A). In another example, the spacer 26 mirrors the location of the frame 42 and wall 47 surrounding the central region 46. In one such embodiment, the spacer 26 defines a void 27 or recess corresponding to the central region 46 may facilitate the use of back-side components 28, such as capacitors, on the second side 12a of the first circuit board 12 and/or the second side 13b of the second circuit board 13. The void 27 can be a recess that extends partially into the spacer 26 or an opening extending completely through the spacer 26. In yet another example, the spacer 26 has a shape corresponding to the socket 30 and all or part of the region enclosed by the frame 42. Further the spacer 26 can include multiple layers of the same of different geometry and of the same or different materials. Numerous variations and embodiments will be apparent in light of the present disclosure.

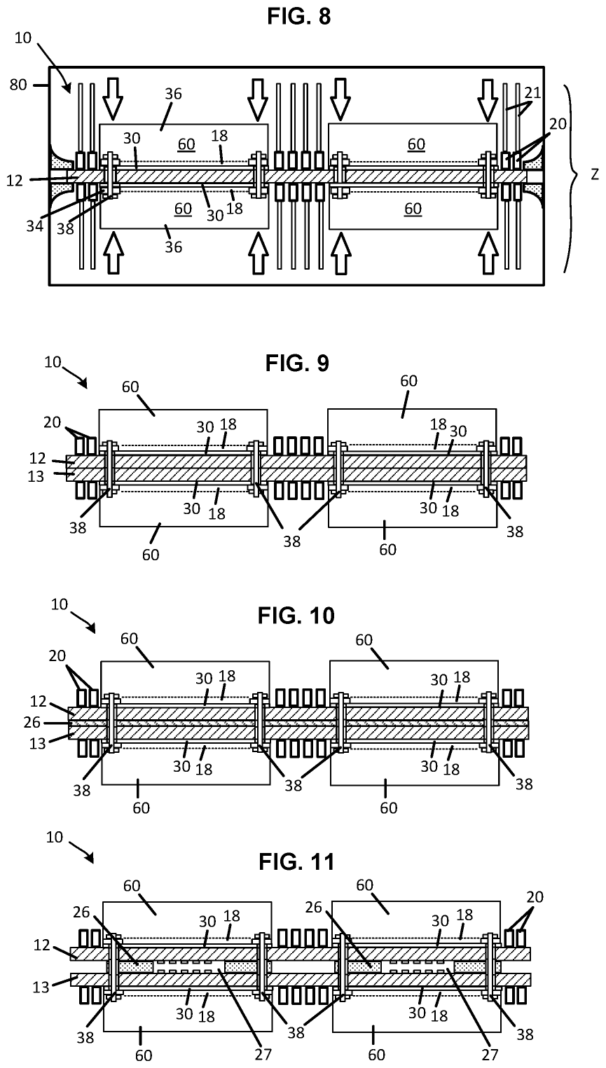

Referring now to FIGS. 8-11, cross-sectional views of the circuit board assemblies 10 of FIGS. 4-7, respectively, are illustrated together with various components, in accordance with some embodiments of the present disclosure. In the example of FIG. 8, the circuit board assembly 10 includes chip packages 60 mounted on opposite sides of the circuit board 12. Each chip package 60 includes, for example, a processor 18 (not visible), springs 34, and heat sink 36. Fasteners 38 extend through the chip packages 60 and circuit board 12 and are tightened to press the chip packages 60 on opposite sides of the circuit board 12 into the socket 30 so that the processors 18 are enabled. As the fasteners 38 are tightened, a distributed load is applied towards the circuit board 12 as shown by arrows in FIG. 8. Memory cards 21 (e.g., dual in-line memory modules, or “DIMMs”) are installed in each memory chip slot 20. In its assembled state, the circuit board 12 has chip packages 60 on both the first side 12a and the second side 12b in mirrored locations. Stated differently, the arrangement of chip packages 60 is symmetrical front to back, at least for one pair of sockets 30.

In this example, the circuit board assembly 10 is secured in a rack-mount chassis 80. The overall vertical or Z dimension of the circuit board assembly 10 is within the limits of a chassis 80 sized for a standard 2U space (two rack units each of ˜1.75″ height). The circuit board assemblies 10 of FIGS. 9-11 are similarly assembled.

One advantage of a mirrored or symmetrical arrangement of sockets 30 is that central regions 46 of the circuit board 12 (or other regions distant from the fasteners 38) cannot deflect or bend away from the chip package 60 as occurs when enabling a processor on only one side of a circuit board. Due to an opposing force from both sides of the circuit board 12, deflection of the circuit board 12 due to a load applied to a socket 30 and chip package 60 on the first side 12a of the circuit board 12 is countered by the equal and opposite load applied to the socket 30 and chip package 60 on the opposite second side 12b of the circuit board 12. As such, the circuit board 12 does not deflect when enabling the mirrored chip packages 60. An additional advantage of a mirrored socket assembly is that the circuit board assembly 10 can effectively use larger sockets 30 that have more contacts 50. In some embodiments, the socket has more than 5000 pins, lands, or other contacts 50. Further, by assembling sockets 30 to opposite sides of the circuit board(s) in mirrored locations, the circuit board assembly 10 fits within the Z dimension of a chassis 80 configured for vertical spacing of a traditional rack-mount system without any sacrifice in computing density. For example, when sockets 30 are mounted to opposite sides of the circuit board assembly 10, the vertical or Z dimension of a single circuit board assembly 10 is no greater than that of two individual circuit boards that have sockets mounted on only one side. In some embodiments, the Z dimension of such an embodiment is actually reduced due to eliminating space between the bottom of the circuit board 12 and the chassis for each of two traditional circuit boards. When the Z dimension is reduced in this way, the chassis 80 for a 2U circuit board assembly 10 may have increased airflow from cooling fans compared to a chassis 80 containing two 1U motherboards having sockets on only one side. Yet a further example of circuit boards 10 in accordance with an embodiment of the present disclosure is that a reduced number of fasteners 38 is required to enable the chip package 60 compared to enabling an equivalently sized chip package on only one side of the circuit board. Since forces are applied to opposite sides 12a, 12b of the circuit board 12 in a mirrored arrangement, such forces are better distributed and more effectively enable the chip package 60, in accordance with some embodiments. Therefore, fewer fasteners 38 are needed, which in turn enables more flexibility in locating conductive traces and the like.

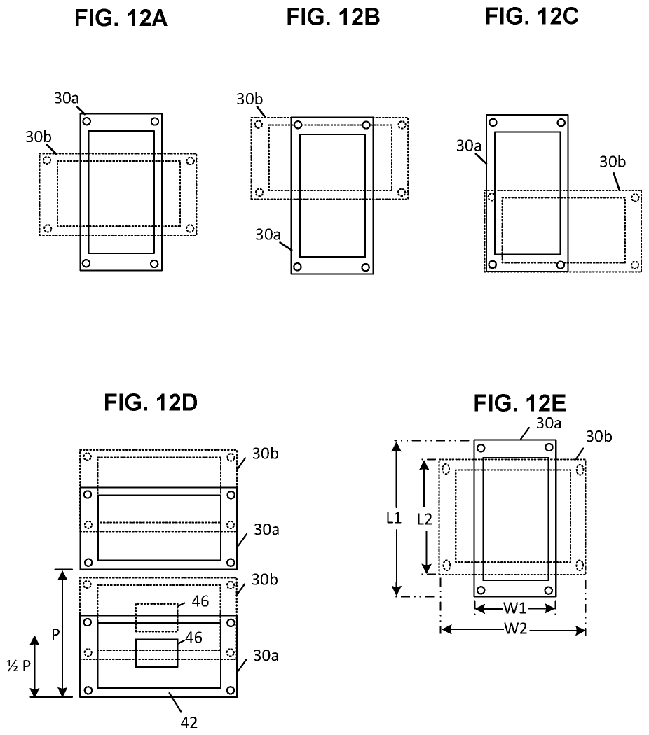

Referring now to FIGS. 12A-12E, plan views illustrate variations in position and alignment between a first socket 30a on a first side 12a and a second socket 30b on a second side 12b of the circuit board 12. For clarity, the second socket 30b is illustrated in broken lines. FIG. 12A illustrates an example where the first socket 30a is rotated 90° with respect to the second socket 30b, defining a plus shape. In this example, the first socket 30a and second socket 30b are horizontally and vertically centered over each other as viewed in plan view. An advantage of such an arrangement is that each of the first socket 30a and second socket 30b can use different fastener openings in the circuit board 12, such as when the sockets 30a, 30b have a different geometry or size.

In the example of FIG. 12B, the first socket 30a is rotated 90° with respect to the second socket 30b, defining a T shape. The first socket 30a and second socket 30b are horizontally centered, but not vertically centered. Instead, the uppermost margin of each socket is aligned (e.g., top edges are aligned). In other embodiments, the vertical position of the second socket 30b is offset with respect to the first socket 30a to an extent between being centered (as shown in FIG. 12A) and top-edge aligned (as shown in FIG. 12B). FIG. 12C illustrates an example of the first socket 30a and second socket 30b defining an L shape, where the bottom and left edges of each socket 30a, 30b are aligned.

FIG. 12D illustrates an example with two first sockets 30a and two second sockets 30b. The first sockets 30a are offset with respect to the second sockets 30b by about ⅓ of the pitch P. In some embodiments, the offset is no greater than ½ pitch P, including no greater than ⅓ pitch P, and no greater than ¼ pitch P. For example, the pitch P between adjacent sockets is defined as the distance between corresponding features on adjacent sockets (e.g., a bottom edge). In some embodiments, the first socket 30a on the first side 12a (including the frame 42 and enclosed region) overlaps at least 50% of the second socket 30b on the second side 12b. In other embodiments, the overlap is at least 60%, at least 75%, at least 85%, or at least 90%.

In some such embodiments, a portion of the frame 42 of the first socket 30a overlaps a central region 46 of a second socket 30b, or vice versa. Such orientation can apply to embodiments in which the first socket 30a is offset, rotated, or both offset and rotated with respect to the second socket 30b. As such, the frame 42 adds to the stiffness of the assembly and reduces or prevents circuit board deflection.

In each of the examples of FIGS. 12A-12D, the first socket 30a has the same size and geometry as the second socket 30b, but this is not required. In some embodiments, the first socket 30a may have a different size and/or different shape compared to the second socket 30b. For example, the first socket 30a has a width W1 and length L1, and the second socket 30b has a width W2 and length L2. As shown in the example of FIG. 12E, the width W2 of the second socket 30b is greater than the width W1 of the first socket 30a and the length L2 of the second socket 30b is less than the length L1 of the first socket 30a.

Example Computing System

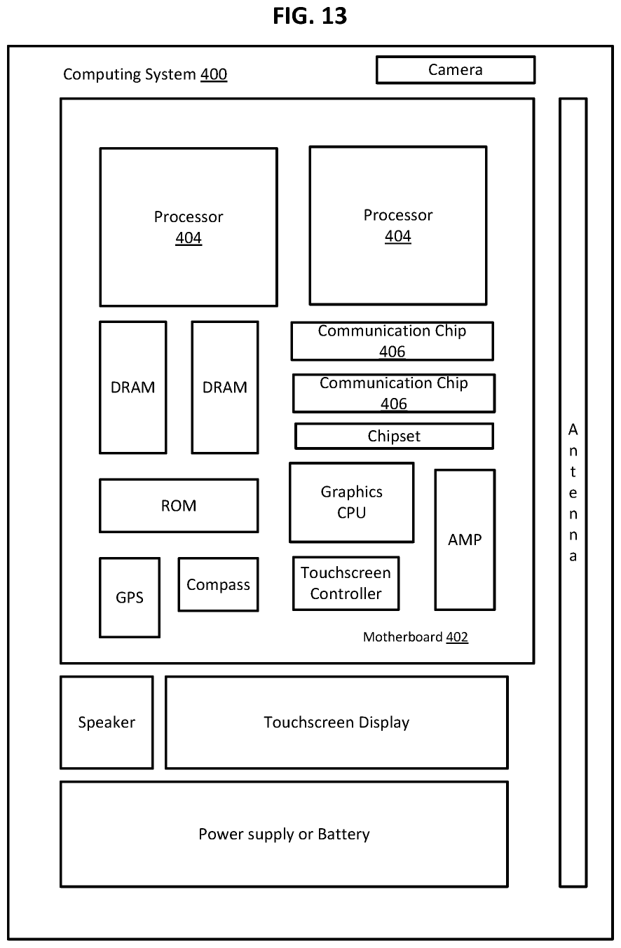

Referring now to FIG. 13, an example computing system 400 is shown that is implemented with one or more of the circuit board assemblies 10 as disclosed herein, in accordance with some embodiments of the present disclosure. As can be seen, the computing system 400 houses a motherboard 402. The motherboard 402 may include a number of components, including, but not limited to, one or more processor 404 and at least one communication chip 406, each of which can be physically and electrically coupled to the motherboard 402, or otherwise integrated therein. As will be appreciated, the motherboard 402 may be, for example, any printed circuit board, whether a main board, a daughterboard mounted on a main board, or the only board of system 400. In accordance with some embodiments, processors 404 can be mounted to opposite sides of the motherboard 402 as variously disclosed herein.

Depending on its applications, computing system 400 may include one or more other components that may or may not be physically and electrically coupled to the motherboard 402. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery or power supply, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). In some embodiments, multiple functions can be integrated into one or more chips (e.g., note that the communication chip 406 can be part of or otherwise integrated into the processor 404).

The communication chip 406 enables wireless communications for the transfer of data to and from the computing system 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processors 404 of the computing system 400 each includes an integrated circuit die packaged within the processor 404. In some embodiments, processors 404 may be mounted in a stacked configuration as variously described herein, where one processor 404 is installed in an LGA socket mounted on a first side of mother board 402 and the other processor 404 is installed in an LGA socket mounted on a second side of mother board 402. The term “processor” may refer to any device or portion of a device that processes, for instance, electronic data from registers and/or memory to transform that electronic data into other electronic data that may be stored in registers and/or memory.

The communication chips 406 also may each include an integrated circuit die packaged within the communication chip 406. In some embodiments, communication chips 406 may be mounted in a stacked configuration as variously described herein, where one communication chip 406 is installed in an LGA socket mounted on a first side of mother board 402 and the other communication chip 406 is installed in an LGA socket mounted on a second side of mother board 402. As will be appreciated in light of this disclosure, note that multi-standard wireless capability may be integrated directly into the processor 404 (e.g., where functionality of any chips 406 is integrated into processor 404, rather than having separate communication chips). Further note that processor 404 may be a chip set having such wireless capability. In short, any number of processor 404 and/or communication chips 406 can be used. Likewise, any one chip or chip set can have multiple functions integrated therein. Further note that processor 404 and communication chip 406 may be arranged in a stacked configuration as variously described herein, whether in a mirrored or non-mirrored fashion, according to some embodiments and as will be appreciated.

In various implementations, the computing system 400 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

### FURTHER EXAMPLE EMBODIMENTS

The following examples pertain to further embodiments, from which numerous permutations and configurations will be apparent.

Example 1 is a circuit board assembly comprising at least one circuit board having a plurality of conductive layers, the at least one circuit board having a first face and an opposite second face; a first chip socket on the first face, the first chip socket aligned with the plurality of through openings; and a second chip socket on the second face, the second chip socket positioned opposite of the first chip socket, such that the first and second chip sockets at least partially overlap one another on opposite sides of the at least one circuit board.

Example 2 includes the subject matter of Example 1, wherein the at least one circuit board defines a plurality of through openings, wherein corresponding openings of each of the first chip socket and the second chip socket are aligned with the plurality of through openings.

Example 3 includes the subject matter of Example 2 and further comprises a fastener extending through one of the plurality of through openings, the fastener retaining the first chip package against the first face and retaining the second chip package against the opposite second face.

Example 4 includes the subject matter of Example 2 or 3 and further comprises a first chip package in the first chip socket; a second chip package in the second chip socket; and a fastener extending through one of the plurality of through openings, the fastener retaining the first chip package in the first chip socket and retaining the second chip package in the second chip socket.

Example 5 includes the subject matter of any of Examples 1-4, wherein the at least one circuit board includes a first circuit board and a second circuit board assembled in a back-to-back arrangement, the first circuit board defining the first face and the second circuit board defining the opposite second face.

Example 6 includes the subject matter of Example 5 and further comprises a spacer between the first circuit board and the second circuit board.

Example 7 includes the subject matter of Example 6, wherein the spacer contacts the first circuit board and the second circuit board in an area between the first chip socket and the second chip socket.

Example 8 includes the subject matter of Example 6 or 7, wherein the spacer comprises an insulative material in contact with the first circuit board and the second circuit board.

Example 9 includes the subject matter of Example 8, wherein the spacer further comprises a metal between layers of the insulative material.

Example 10 includes the subject matter of any of Examples 6-9, wherein the spacer extends in a non-continuous fashion so as to define a void between the first circuit board and the second circuit board.

Example 11 includes the subject matter of Example 10, further comprising one or more components on the first and/or second circuit boards, wherein the one or more components extend into the void.

Example 12 includes the subject matter of Example 11, wherein the one or more components include one or more capacitors.

Example 13 includes the subject matter of any of Examples 1-3 or 6-12 and further comprises a first processor in the first chip socket and a second processor in the second chip socket.

Example 14 includes the subject matter of Example 13 and further comprises a first heat sink coupled to the first processor; first springs disposed between the fasteners and the first processor; a second heat sink coupled to the second processor; and second springs disposed between the fasteners and the second processor.

Example 15 includes the subject matter of Example 13 or 14, wherein the first chip socket defines a first central region and the second chip socket defines a second central region opposite the first central region, the first central region and the second central region each including at least one capacitor electrically coupled to the at least one circuit board.

Example 16 includes the subject matter of Example 15, wherein the spacer defines an opening corresponding to the first central region and the second central region.

Example 17 includes the subject matter of any of Examples 1-16 and further comprises a third chip socket on the first face; and a fourth chip socket on the second face, the fourth chip socket positioned opposite of the third socket.

Example 18 includes the subject matter of any of Examples 1-17, wherein the first and second chip sockets are arranged in a mirrored fashion with respect to one another.

Example 19 includes the subject matter of any of Examples 1-17, wherein the first and second chip sockets are arranged in a non-mirrored fashion with respect to one another.

Example 20 includes the subject matter of any of Examples 1-19, wherein the first chip socket and the second chip socket are selected from (i) a land grid array socket, (ii) a pin grid array socket, and (iii) a ball grid array socket.

Example 21 is an electronic system comprising the circuit board assembly of any of Examples 1-20.

Example 22 is a server computer system comprising the circuit board assembly of any of Examples 1-20.

Example 23 is a computing system comprising a circuit board assembly with a first face and an opposite second face; a first chip socket mounted to the first face; and a second chip socket mounted to the second face, the second chip socket at least partially overlapping the first chip socket; wherein the first chip socket and the second chip socket are each configured to receive a processor.

Example 24 includes the subject matter of Example 23, wherein the first chip socket is centered vertically and horizontally with respect to the second chip socket.

Example 25 includes the subject matter of any of Examples 23 or 24, wherein the first chip socket is rotated 90° with respect to the second chip socket.

Example 26 includes the subject matter of any of Examples 23-25, wherein at least 50% of the first chip socket is overlapped by the second chip socket.

Example 27 includes the subject matter of any of Examples 23-26, wherein an edge of the first chip socket is aligned with an edge of the second chip socket.

Example 28 includes the subject matter of any of Examples 23-27, wherein at least one dimension of the first chip socket differs from a corresponding dimension of the second chip socket.

Example 29 includes the subject matter of Example 23, wherein when viewed looking at the first face, areas of the first chip socket and the second chip socket define a shape selected from (i) a plus shape, (ii) a T shape, and (iii) an L shape.

Example 30 includes the subject matter of any of Examples 23-26, wherein a frame of the first chip socket overlaps a central region of the second chip socket.

Example 31 includes the subject matter of any of Examples 21-28, wherein the circuit board assembly includes a first circuit board and a second circuit board assembled in a back-to-back arrangement, the first circuit board defining the first face and the second circuit board defining the opposite second face.

Example 32 includes the subject matter of any of Examples 23-31 and further comprises an insulative spacer between the first circuit board and the second circuit board.

Example 33 includes the subject matter of any of Examples 23, 24, 27, 31 or 32, wherein the circuit board assembly defines a plurality of through openings aligned with the first chip socket and with the second chip socket, wherein the computing system includes fasteners extending through each of the plurality of through openings, and wherein the fasteners retain the first chip socket against the first face and retain the second chip socket against the opposite second face.

Example 34 includes the subject matter of any of Examples 23-33, wherein the circuit board assembly is configured as a motherboard.

Example 35 includes the subject matter of any of Examples 23-34 and further comprises a first processor installed in the first chip socket; a second processor installed in the second chip socket; a plurality of memory modules; a power supply; and one or more mass storage device.

Example 36 includes the subject matter of any of Examples 23-35 and further comprises an additional pair of chip sockets, the additional pair of chip sockets including a third chip socket on the first face and a corresponding fourth chip socket on the second face, wherein the third chip socket is positioned opposite the fourth chip socket.

Example 37 includes the subject matter of any of Examples 23-36, wherein the first chip socket and the second chip socket each include at least 4000 processor contacts.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future-filed applications claiming priority to this application may claim the disclosed subject matter in a different manner and generally may include any set of one or more limitations as variously disclosed or otherwise demonstrated herein.

What is claimed is:

1. A circuit board assembly comprising:
at least one circuit board having a plurality of conductive layers, the at least one circuit board having a first face and an opposite second face;
a first chip socket on the first face, the first chip socket aligned with the plurality of through openings; and
a second chip socket on the second face, the second chip socket positioned opposite of the first chip socket, such that the first and second chip sockets at least partially overlap one another on opposite sides of the at least one circuit board.

2. The circuit board assembly of claim 1, wherein the at least one circuit board defines a plurality of through openings, wherein corresponding openings of each of the first chip socket and the second chip socket are aligned with the plurality of through openings.

3. The circuit board assembly of claim 2 further comprising a fastener extending through one of the plurality of through openings, the fastener retaining the first chip package against the first face and retaining the second chip package against the opposite second face.

4. The circuit board assembly of claim 2 further comprising:
a first chip package installed in the first chip socket;
a second chip package installed in the second chip socket; and
a fastener extending through one of the plurality of through openings, the fastener retaining the first chip package in the first chip socket and retaining the second chip package in the second chip socket.

5. The circuit board assembly of claim 1, wherein the at least one circuit board includes a first circuit board and a second circuit board assembled in a back-to-back arrangement, the first circuit board defining the first face and the second circuit board defining the opposite second face.

6. The circuit board assembly of claim 5 further comprising a spacer between the first circuit board and the second circuit board.

7. The circuit board assembly of claim 6, wherein the spacer contacts the first circuit board and the second circuit board in an area between the first chip socket and the second chip socket.

8. The circuit board assembly of claim 6, wherein the spacer extends in a non-continuous fashion so as to define a void between the first circuit board and the second circuit board.

9. The circuit board assembly of claim 8, further comprising one or more components on the first and/or second circuit boards, wherein the one or more components extend into the void.

10. The circuit board assembly of claim 9, wherein the one or more components include one or more capacitors.

11. The circuit board assembly of claim 1, wherein the first chip socket defines a first central region and the second chip socket defines a second central region opposite the first central region, the first central region and the second central region each including at least one capacitor electrically coupled to the at least one circuit board.

12. The circuit board assembly of claim 1 further comprising:
a third chip socket on the first face; and
a fourth chip socket on the second face, the fourth chip socket positioned opposite of the third chip socket, such that the third and fourth chip sockets at least partially overlap one another on opposite sides of the at least one circuit board.

13. The circuit board assembly of claim 1, wherein the first and second chip sockets are arranged in a mirrored fashion with respect to one another.

14. The circuit board assembly of claim 1, wherein the first and second chip sockets are arranged in a non-mirrored fashion with respect to one another.

15. An electronic system comprising the circuit board assembly of claim 1.

16. The electronic system of claim 15 configured as a server computer system.

17. A computing system comprising:
a circuit board assembly with a first face and an opposite second face;
a first chip socket mounted to the first face; and
a second chip socket mounted to the second face, the second chip socket at least partially overlapping the first chip socket;
wherein the first chip socket and the second chip socket are each configured to receive a processor.

18. The computing system of claim 17, wherein the first chip socket is centered vertically and horizontally with respect to the second chip socket.

19. The computing system of claim 17, wherein the first chip socket is rotated 90° with respect to the second chip socket.

20. The computing system of claim 17, wherein a frame of the first chip socket overlaps a central region of the second chip socket.
